(19) United States
(12) Patent Application Publication
(10) Pub. No.: US 2026/0255954 A1
(43) Pub. Date: Aug. 27, 2026

(54) SEMICONDUCTOR MEMORY DEVICE AND MANUFACTURING METHOD THEREOF

(71) Applicant: Fujian Jinhua Integrated Circuit Co., Ltd., Fujian (CN)

(72) Inventor: Yukihiro NAGAI, Fujian (CN)

(73) Assignee: Fujian Jinhua Integrated Circuit Co., Ltd., Fujian (CN)

(21) Appl. No.: 19/458,946

(22) Filed: Jan. 26, 2026

(30) Foreign Application Priority Data
Feb. 21, 2025 (CN) 202510199110.3

(51) Int. Cl. H10W 20/45; H10B 12/00; H10D 1/68; H10W 20/00; H10W 20/44; H10W 20/48

(52) U.S. Cl. CPC H10W 20/455; H10B 12/03; H10B 12/05; H10B 12/482; H10B 12/485; H10B 12/488; H10D 1/714; H10W 20/077; H10W 20/4403; H10W 20/48

(57) ABSTRACT

Embodiments of the present disclosure provide a semiconductor memory device and a manufacturing method of the semiconductor memory device. The semiconductor memory device includes: a substrate, a plurality of stacked structures, a word line, a bit line, and a first barrier layer. The plurality of stacked structures are isolated from each other. The stacked structure includes semiconductor layers. The semiconductor layer includes a first doped region, a channel region, and a second doped region. The word line extends along a vertical direction and is adjacent to the channel region. The bit line extends along a horizontal direction and is electrically connected to the first doped region. The first barrier layer is disposed between adjacent bit lines, and the first barrier layer including a semiconductor material.

### CROSS-REFERENCE TO RELATED APPLICATION

This application claims priority to Chinese Patent Application No. 202510199110.3, filed on February 21, 2025, which is hereby incorporated by reference in its entirety.

### TECHNICAL FIELD

The present disclosure relates to the technical field of semiconductor technology, particularly to a semiconductor memory device and a manufacturing method of the semiconductor memory device.

### BACKGROUND

With the development of semiconductor technology, semiconductor memory devices are widely used in various electronic devices. A semiconductor memory device includes word line(s) (WL(s)), bit line(s) (BL(s)), transistor(s), and capacitor(s). A gate of a transistor is connected to a word line, a drain of the transistor is connected to a bit line, and a source of the transistor is connected to a capacitor. The transistor is controlled to switch on or switch off through the word line, and data is read from or written to the capacitor through the bit line.

However, adjacent bit lines are prone to electrical coupling, which degrades performance of the semiconductor memory device.

### SUMMARY

Embodiments of the present disclosure provide a semiconductor memory device and a manufacturing method of the semiconductor memory device, which achieve the effect of reducing coupling between bit lines.

In a first aspect, an embodiment of the present disclosure provides a semiconductor memory device. The semiconductor memory device includes: a substrate; a plurality of stacked structures disposed on the substrate and isolated from one another in a vertical direction. The stacked structure includes semiconductor layers. The semiconductor layer includes a first doped region, a channel region, and a second doped region. The semiconductor memory device further includes a word line extending along the vertical direction and being adjacent to the channel region; a bit line extending along a horizontal direction and being electrically connected to the first doped region; and a first barrier layer disposed between adjacent bit lines, and the first barrier layer is made of a material including a semiconductor material.

In a possible implementation, the first barrier layer surrounds a portion of the bit line and a portion of the first doped region.

In a possible implementation, the first barrier layer covers a portion of an upper surface of the bit line, a portion of a lower surface of the bit line, and a portion of a side surface of the bit line. The upper surface and the lower surface of the bit line face each other along the vertical direction.

In a possible implementation, the stacked structure further includes an insulating layer disposed between adjacent semiconductor layers. Surfaces of the insulating layer and the first barrier layer that are opposite are overlapping.

In a possible implementation, the stacked structure further includes a second barrier layer disposed between the semiconductor layer and the first barrier layer.

In a possible implementation, in the vertical direction, an orthographic projection of the first barrier layer onto the substrate is spaced apart from an orthographic projection of the channel region onto the substrate.

In a possible implementation, the semiconductor memory device further includes a first electrode, a second electrode, and a dielectric layer disposed between the first electrode and the second electrode. The first electrode is electrically connected to the second doped region.

In a possible implementation, the semiconductor memory device further includes a first metal silicide and a second metal silicide. The first metal silicide is disposed between the bit line and the first doped region, and the second metal silicide is disposed between the first electrode and the second doped region.

In a possible implementation, the word line includes a first word line and a second word line. The first word line is adjacent to a first side of the channel region, and the second word line is adjacent to a second side of the channel region. The second side and the first side of the channel region face each other along an extension direction of the bit line.

The semiconductor memory device provided in the embodiments of the present disclosure includes a substrate, a plurality of stacked structures, a word line, a bit line, and a first barrier layer. The plurality of stacked structures are disposed on the substrate and isolated from one another in a vertical direction. The stacked structure includes semiconductor layers. The semiconductor layer includes a first doped region, a channel region, and a second doped region. The word line extends along the vertical direction and is adjacent to the channel region. The bit line extends along a horizontal direction and is electrically connected to the first doped region. The first barrier layer is disposed between adjacent bit lines, and the first barrier layer is made of a material including a semiconductor material. The application of the semiconductor material to isolate adjacent bit lines can reduce the electrical coupling between adjacent bit lines, thereby enhancing performance of the semiconductor memory device.

In a second aspect, an embodiment of the present disclosure provides a manufacturing method of a semiconductor memory device. The method includes: providing a substrate, and forming stacked structures, a word line, a bit line and a first barrier layer. The stacked structures are disposed on the substrate and isolated from one another in a vertical direction. The stacked structure includes semiconductor layers. The semiconductor layer includes a first doped region, a channel region, and a second doped region. The word line extends along the vertical direction and is adjacent to the channel region. The bit line extends along a horizontal direction and is electrically connected to the first doped region. The first barrier layer is disposed between adjacent bit lines, and the first barrier layer is made of a material including a semiconductor material.

In a possible implementation, the first barrier layer surrounds a portion of the bit line and a portion of the first doped region.

In a possible implementation, the first barrier layer covers a portion of an upper surface of the bit line, a portion of a lower surface of the bit line, and a portion of a side surface of the bit line. The upper surface and the lower surface of the bit line face each other along the vertical direction.

In a possible implementation, forming the stacked structures, the word line, the bit line and the first barrier layer further includes: forming an insulating layer disposed between adjacent semiconductor layers. Surfaces of the insulating layer and the first barrier layer that are opposite are overlapping.

In a possible implementation, forming the stacked structures, the word line, the bit line and the first barrier layer further includes: forming a second barrier layer disposed between the semiconductor layer and the first barrier layer.

In a possible implementation, in the vertical direction, an orthographic projection of the first barrier layer onto the substrate is spaced apart from an orthographic projection of the channel region onto the substrate.

In a possible implementation, forming the stacked structures, the word line, the bit line and the first barrier layer further includes: forming a first electrode, a second electrode, and a dielectric layer disposed between the first electrode and the second electrode. The first electrode is electrically connected to the second doped region.

In a possible implementation, forming the stacked structures, the word line, the bit line and the first barrier layer further includes: forming a first metal silicide and a second metal silicide. The first metal silicide is disposed between the bit line and the first doped region, and the second metal silicide is disposed between the first electrode and the second doped region.

In a possible implementation, the word lines include a first word line and a second word line. The first word line is adjacent to a first side of each channel region, and the second word line is adjacent to a second side of each channel region. The second side and the first side of each channel region face each other along an extension direction of the bit line.

According to the manufacturing method of a semiconductor memory device, a plurality of stacked structures, a word line, a bit line and a first barrier layer are formed on a substrate. The plurality of stacked structures are isolated from one another in a vertical direction. The stacked structure includes semiconductor layers. The semiconductor layer includes a first doped region, a channel region, and a second doped region. The word line extends along the vertical direction and is adjacent to the channel region. The bit line extends along a horizontal direction and is electrically connected to the first doped region. The first barrier layer is disposed between adjacent bit lines, and the first barrier layer is made of a material including a semiconductor material. The application of the semiconductor material to isolate adjacent bit lines can reduce the electrical coupling between adjacent bit lines, thereby enhancing performance of the semiconductor memory device.

### BRIEF DESCRIPTION OF THE DRAWINGS

The drawings herein are incorporated into the specification and constitute a part thereof, illustrating embodiments in accordance with the present disclosure, and are used together with the specification to explain the principles of the present disclosure.

FIG. 1 is a perspective view of a semiconductor memory device according to the present disclosure.

FIG. 2 is a cross-sectional view of a semiconductor memory device according to the present disclosure.

FIG. 3 is a perspective view after the formation of initial layers and insulating layers according to the present disclosure.

FIG. 4 is a top view after the formation of initial layers and insulating layers according to the present disclosure.

FIG. 5 is a cross-sectional view after the formation of initial layers and insulating layers according to the present disclosure.

FIG. 6 is a perspective view after the formation of word lines according to the present disclosure.

FIG. 7 is a top view after the formation of word lines according to the present disclosure.

FIG. 8 is a perspective view after the formation of first doped regions according to the present disclosure.

FIG. 9 is a top view after the formation of first doped regions according to the present disclosure.

FIG. 10 is a cross-sectional view after the formation of first doped regions according to the present disclosure.

FIG. 11 is a perspective view after the formation of bit lines according to the present disclosure.

FIG. 12 is a top view after the formation of bit lines according to the present disclosure.

FIG. 13 is a cross-sectional view after the formation of bit lines according to the present disclosure.

FIG. 14 is a perspective view after the removal of a portion of insulating layers according to the present disclosure.

FIG. 15 is a cross-sectional view after the removal of a portion of insulating layers according to the present disclosure.

FIG. 16 is a perspective view after the formation of a first barrier layer according to the present disclosure.

FIG. 17 is a top view after the formation of a first barrier layer according to the present disclosure.

FIG. 18 is a cross-sectional view after the formation of a first barrier layer according to the present disclosure.

FIG. 19 is a perspective view after the formation of a second doped region according to the present disclosure.

FIG. 20 is a top view after the formation of a second doped region according to the present disclosure.

FIG. 21 is a cross-sectional view after the formation of a second doped region according to the present disclosure.

FIG. 22 is a perspective view after the formation of a second electrode according to the present disclosure.

FIG. 23 is a top view after the formation of a second electrode according to the present disclosure.

FIG. 24 is a cross-sectional view after the formation of a second electrode according to the present disclosure.

### DESCRIPTION OF THE EMBODIMENTS

Exemplary embodiments will be described in detail herein, and presented illustratively in the accompanying drawings. In the following description, when referring to the accompanying drawings, the same number in different drawings indicates the same or similar elements, unless otherwise indicated. The implementations described in the following exemplary embodiments do not represent all embodiments being consistent with the present disclosure. Rather, they are merely examples of apparatuses and methods being consistent with some aspects of the present disclosure as detailed in the appended claims.

In related technologies, adjacent bit lines are often isolated by an inter layer dielectric (ILD). However, adjacent bit lines are prone to electrical coupling. For example, parasitic capacitance formed between adjacent bit lines and the inter layer dielectric leads to degradation of performance of a semiconductor memory device.

According to the semiconductor memory device provided in the embodiments of the present disclosure, a first barrier layer is disposed between adjacent bit lines, and the first barrier layer is made of a material including a semiconductor material. The application of the semiconductor material to isolate adjacent bit lines can reduce the electrical coupling between adjacent bit lines, thereby enhancing performance of the semiconductor memory device.

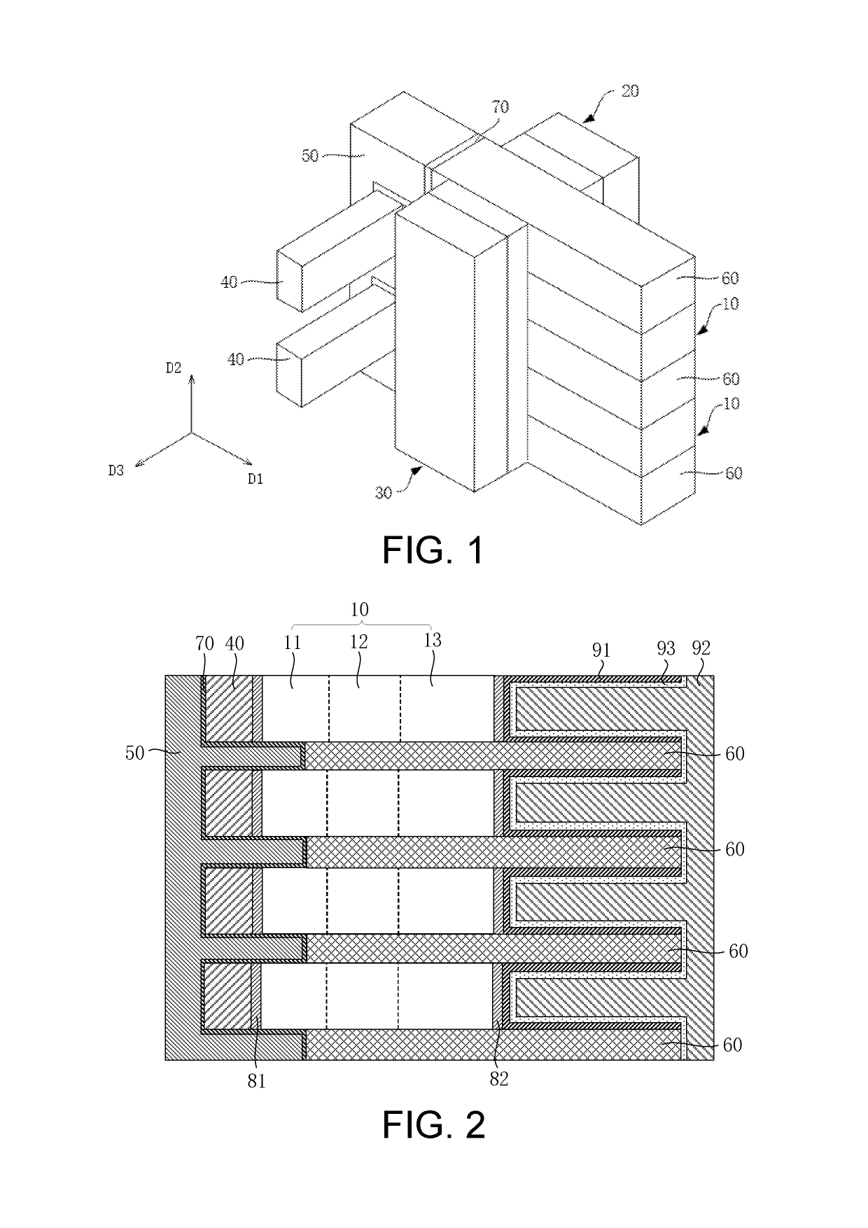

With reference to FIGS. 1, 2, 23 and 24, an embodiment of the present disclosure provides a semiconductor memory device. For example, the semiconductor memory device is a dynamic random access memory (DRAM). As shown in FIGS. 1 and 24, the semiconductor memory device includes a substrate 100, a plurality of stacked structures, a word line, a bit line 40, and a first barrier layer 50. The substrate 100 provides support for the structures above it, such as the stacked structures, the word line, the bit lines 40, and the first barrier layer 50. The substrate 100 is, for example, a silicon substrate, a silicon-containing (e.g., silicon-germanium) substrate, a silicon-on-insulator (SOI) substrate, or the like.

The plurality of stacked structures are disposed on the substrate 100 and isolated from one another in a vertical direction. The stacked structure includes semiconductor layers 10. The semiconductor layer 10 includes a first doped region 11, a channel region 12, and a second doped region 13. The plurality of stacked structures are arranged at intervals on the substrate 100. An arrangement direction of the plurality of stacked structures is indicated with D3 in FIG. 1.

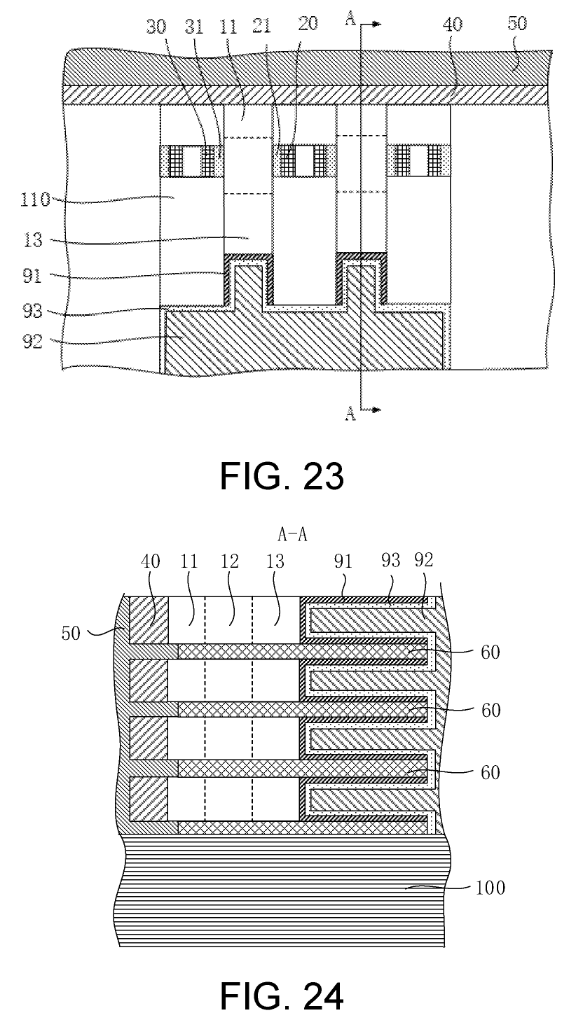

As shown in FIG. 23, a third barrier layer 110 is formed (filled) at least between adjacent stacked structures. The third barrier layer 110 is applied to achieve mutual isolation among the stacked structures. The third barrier layer 110 is also disposed on the substrate 100 and extends along the vertical direction, ensuring that there is no mutual conductivity between the stacked structures in the vertical direction. As an example, a top surface of the third barrier layer 110 can be higher than or flush with a top surface of the stacked structures. Here, the top surface refers to a surface away from the substrate 100, and the vertical direction refers to a direction perpendicular to a top surface of the substrate 100, as indicated with D2 in FIG. 1. The third barrier layer 110 is made of a material including an insulating material, such as silicon oxide, silicon nitride, silicon carbonitride, or the like.

Each stacked structure includes semiconductor layers 10. For example, each stacked structure includes at least two semiconductor layers 10 which are arranged at intervals in the vertical direction. The semiconductor layers 10 in each stacked structure may either be in contact with the substrate 100 or be spaced apart from the substrate 100. The semiconductor layer 10 is made of a material including a semiconductor material, such as monocrystalline silicon, polycrystalline silicon, amorphous silicon, or the like.

Each semiconductor layer includes a first doped region 11, a channel region 12, and a second doped region 13 which are arranged in sequence. That is, the channel region 12 is connected to the first doped region 11 on one side and the second doped region 13 on the other side. The first doped region 11, the channel region 12, and the second doped region 13 are adjacent in sequence and are parallel to the top surface of the substrate 100. An arrangement direction of the first doped region 11, the channel region 12, and the second doped region 13 is the direction D1 shown in FIG. 1. This direction can also be considered as an extension direction of the semiconductor layers 10.

The surfaces of the first doped region 11 and the channel region 12 that face each other may be overlapping, for example, completely coincide. The surfaces of the second doped region 13 and the channel region 12 that face each other may be overlapping, for example, completely coincide. Both the first doped region 11 and the second doped region 13 can be heavily doped regions, with doping achieved, for example, through ion implantation. The first doped region 11 can serve as a drain (Drain) and is connected to a bit line 40, while the second doped region 13 can serve as a source (Source) and is connected to a capacitor.

To achieve mutual isolation between adjacent semiconductor layers 10 within the same stacked structure, the stacked structure further includes an insulating layer 60. The insulating layer 60 is disposed between adjacent semiconductor layers 10. The insulating layer 60 is formed (filled) at least between adjacent semiconductor layers 10 and is in complete contact with surfaces of two adjacent semiconductor layers 10 that face each other, ensuring effective isolation among the semiconductor layers 10. The insulating layer 60 is made of a material including silicon oxide, silicon nitride, phosphosilicate glass, or the like.

Further reference is made to FIG. 1, FIGS. 2 and 24, the bit line 40 is disposed on the substrate 100 and extends along a horizontal direction. The horizontal direction is parallel to the top surface of the substrate 100. The bit line 40 is electrically connected to the first doped region 11. That is, the bit line 40 can be electrically conductive with the first doped region 11. In some possible implementations, a height of the bit line 40 matches a height of the semiconductor layer 10. A top surface of the bit line 40 is higher than a bottom surface of the semiconductor layers 10 to which the bit line 40 is connected and is lower than or flush with a top surface of its connected semiconductor layer 10. Alternatively, a bottom surface of the bit line 40 is higher than or flush with the bottom surface of its connected semiconductor layer 10 and is lower than the top surface of its connected semiconductor layer 10. Specifically, the top surface of the bit line 40 is flush with the top surface of its connected semiconductor layer 10, and the bottom surface of the bit line 40 is flush with the bottom surface of its connected semiconductor layer 10. That is, the bit line 40 and the semiconductor layer 10 are disposed in the same layer, facilitating fabrication of the bit line 40 and also improving transmission performance between the bit line 40 and the corresponding semiconductor layer 10.

In some possible examples, an extension direction of the bit line 40 is parallel to an arrangement direction of the plurality of stacked structures. In this way, the bit line 40 can be connected to the plurality of semiconductor layers 10 disposed in different stacked structures, thereby simplifying the structure of the semiconductor memory device and thus facilitating an increase in storage density. The extension direction of the bit line 40 is the direction D3 shown in FIG. 1. The bit line 40 can be of a single-layer or multiple-layer structure. As an example, the bit line 40 includes a first conductor layer. The first conductor layer is made of a material including a metal material, for example, a low-resistance metal material including tungsten, aluminum, or copper. The specific structure of the bit line 40 in the embodiments of the present disclosure is not limited.

As shown in FIG. 2, a first metal silicide 81 is further disposed between the bit line 40 and the first doped region 11. That is, the semiconductor memory device further includes the first metal silicide 81, which is disposed between the bit line 40 and the first doped region 11. The first metal silicide 81 is in contact with both the bit line 40 and the first doped region 11 and achieves electrical conduction between the bit line 40 and the first doped region 11. By providing the first metal silicide 81, the contact resistance between the bit line 40 and the first doped region 11 can be reduced. The first metal silicide 81 is made of a material including, for example, tungsten silicide, titanium silicide, cobalt silicide or the like.

It can be understood that there can be a plurality of bit lines 40, and the plurality of bit lines 40 are arranged at intervals in the vertical direction to avoid connection between adjacent bit lines 40. The number of the bit lines 40 can be consistent with the number of semiconductor layers 10 in the stacked structures, enabling each semiconductor layer 10 within each stacked structure to be individually lead out through the corresponding bit line 40.

Further reference is made to FIGS. 1, 2 and 24, the word line is disposed on the substrate 100 and extends along a vertical direction. Specifically, the word line extends along a direction away from a top surface of the substrate 100. The word line is adjacent to the channel region 12 to form a gate, thereby controlling the channel region 12 to switch on or off. The word line can be aligned with channel regions 12 of the plurality of semiconductor layers 10 in the same stacked structure, thereby simultaneously controlling the plurality of channel regions 12 to switch on or off.

In some possible implementations, the word line includes a first word line 20 and a second word line 30. The first word line 20 is adjacent to a first side of the channel region 12, and the second word line 30 is adjacent to a second side of the channel region 12. The second side and the first side of the channel region 12 face each other along an extension direction of the bit line 40. As shown in FIG. 1, the first word line 20 and the second word line 30 are respectively disposed on the first side and the second side of the channel region 12. The first word line 20 is adjacent to the first side of the channel region 12 and faces at least a portion of the channel region 12. The second word line 30 is adjacent to the second side of the channel region 12 and faces at least a portion of the channel region 12. The first side and the second side of the channel region 12 face each other along the extension direction of the bit line 40. In this way, the channel region 12 can be controlled through the two word lines.

It can be understood that in the first word line 71 and the second word line 72, regions facing the channel region 12 and aligned along the extension direction of the bit line 40 form a gate structure. The first word line 20 and the second word line 30 can either have the same or different structures. The first word line 20 and the second word line 30 can be of a single-layer or multiple-layer structure, for example, including a second conductor layer. The second conductor layer is made of a material including a semiconductor material such as doped polycrystalline silicon, doped amorphous silicon, or the like, or a low-resistance metal such as tungsten, aluminum, copper, or the like, which is not limited in the embodiments of the present disclosure.

In order to achieve the control functions of the first word line 20 and the second word line 30, the semiconductor memory device further includes a first gate dielectric layer 21 and a second gate dielectric layer 31. The first gate dielectric layer 21 is disposed at least between the first word line 20 and the channel region 12, and the second gate dielectric layer 31 is disposed at least between the second word line 30 and the channel region 12. As an example, the first gate dielectric layer 21 extends along the vertical direction, namely, the first gate dielectric layer 21 is also disposed between the first word line 20 and the insulating layer 60. As an example, the second gate dielectric layer 31 extends along the vertical direction, namely, the second gate dielectric layer 31 is also disposed between the second word line 30 and the insulating layer 60. The first gate dielectric layer 21 and the second gate dielectric layer 31 are made of a material including silicon oxide, hafnium oxide, etc. In the extension direction of the bit line 40, thicknesses of the first gate dielectric layer 21 and the second gate dielectric layer 31 can be equal.

Further reference is made to FIGS. 1 and 2, the semiconductor memory device further includes a first barrier layer 50 which is disposed between adjacent bit lines 40. For example, the first barrier layer 50 is formed (filled) at least between adjacent bit lines 40. The first barrier layer 50 is made of a material including a semiconductor material including, for example, SiGe, SiC, SiP, Si, etc. The first barrier layer 50 is applied to isolate adjacent bit lines 40, thereby avoiding the connection between adjacent bit lines 40, and ensuring mutual isolation between adjacent bit lines 40. Meanwhile, since the first barrier layer 50 is made of a material including a semiconductor material, electrical coupling between adjacent bit lines 40 can be reduced, thereby enhancing the performance of the semiconductor memory device.

In an example where an insulating layer 60 is disposed between adjacent semiconductor layers 10, surfaces of the insulating layer 60 and the first barrier layer 50 that face each other are overlapping, for example, completely coincide. In this way, the insulating layer 60 isolates adjacent semiconductor layers 10, and the first barrier layer 50 isolates adjacent bit lines 40. In addition, the bit line 40 and the semiconductor layer 10 are disposed in the same layer, and the insulating layer 60 and the first barrier layer 50 are in the same layer. This arrangement ensures reliable isolation among the overall structure formed by the bit lines 40 and the semiconductor layers 10, thereby preventing electrical conduction.

Further reference is made to FIGS. 1, 2 and 24, in the vertical direction, an orthographic projection of the first barrier layer 50 onto the substrate 100 is spaced apart from an orthographic projection of the channel region 12 onto the substrate 100. In this way, a surface of the first barrier layer 50 facing the insulating layer 60 is located on a side of the channel region 12 away from the second doped region 13. That is, in the vertical direction, the first barrier layer 50 and the insulating layer 60 do not overlap, preventing the first barrier layer 50 from extending beneath the channel region 12, thus facilitating the formation of the first word line 20 and the second word line 30 beside the channel region 12 and ensuring the gate-control capabilities of the first word line 20 and the second word line 30.

In some possible examples, the first barrier layer 50 surrounds a portion of the bit line 40. For example, a surface of the first barrier layer 50 facing the insulating layer 60 is flush with a surface of the bit line 40 facing the semiconductor layer 10, to avoid contact and conduction between the first barrier layer 50 and the semiconductor layer 10. The first barrier layer 50 covers a portion of an upper surface of the bit line 40, a portion of a lower surface of the bit line 40, and a portion of a side surface of the bit line 40. The upper surface and the lower surface of the bit line 40 are opposite along the vertical direction. The portion of the side surface of the bit line 40 refers to a portion of a surface of the bit line 40 that is away from the semiconductor layer 10. In the extension direction of the bit line 40, a width of the first barrier layer 50 is, for example, equivalent to a width of the insulating layer 60. Specifically, in the extension direction of the bit line 40, opposing surfaces of the first barrier layer 50 are aligned with opposing surfaces of the insulating layer 60.

In some other possible examples, the first barrier layer 50 surrounds a portion of the bit line 40 and a portion of the first doped region 11. That is, the first barrier layer 50 encircles a portion of the bit line 40 and extends between adjacent first doped regions 11. The first barrier layer 50 covers a portion of an upper surface of the bit line 40, a portion of a lower surface of the bit line 40, and a portion of a side surface of the bit line 40. The upper surface and the lower surface of the bit line 40 are opposite along the vertical direction, the portion of the side surface of the bit line 40 refers to a portion of a surface of the bit line 40 that is away from the semiconductor layer 10.

Furthermore, the first barrier layer 50 further covers a portion of an upper surface and a portion of a lower surface of the first doped regions 11. The upper surface and the lower surface of the first doped region 11 are opposite along the vertical direction. In the extension direction of the bit line 40, a width of the first barrier layer 50 is, for example, equivalent to a width of the insulating layer 60. Specifically, in the extension direction of the bit line 40, opposing surfaces of the first barrier layer 50 are aligned with opposing surfaces of the insulating layer 60.

In some possible implementations, the stacked structure further includes a second barrier layer 70 disposed between the semiconductor layer 10 and the first barrier layer 50. In this way, contact between the first barrier layer 50 and the semiconductor layer 10 can be avoided, thereby reducing the influence between the first barrier layer 50 and the semiconductor layer 10, and ensuring the performance of the semiconductor memory device. The second barrier layer 70 can further extend between the bit line 40 and the first barrier layer 50 to form an integrated film layer, facilitating the formation of the second barrier layer 70. The second barrier layer 70 is made of a material including silicon oxide, a high-dielectric-constant material, etc.

Further reference is made to FIGS. 1 and 2, the semiconductor memory device further includes a first electrode 91, a second electrode 92, and a dielectric layer 93 disposed between the first electrode 91 and the second electrode 92. The first electrode 91 is electrically connected to the second doped region 13. By providing the first electrode 91, the second electrode 92, and the dielectric layer 93, a capacitor structure is formed to achieve a storage function of the semiconductor memory device. The insulating layer 60 can further extend between adjacent first electrodes 91 to isolate various first electrodes 91.

The first electrode 91 is electrically connected to the second doped region 13. For example, the first electrode 91 is disposed on a side of the second doped region 13 away from the first doped region 11 and is in electrical conduction with the second doped region 13. The first electrode 91, for example, covers a side surface of the second doped region 13, a portion of a top surface of the insulating layer 60, and a portion of a bottom surface of the insulating layer 60. The top surface and the bottom surface of the insulating layer 60 are oppositely disposed along the vertical direction. A plurality of first electrodes 91 can be provided, such that a corresponding first electrode 91 is disposed on a side of each second doped region 13. One second electrode 92 is provided, allowing the plurality of first electrodes 91 to share one second electrode 92. The first electrode 91 and the second electrode 92 are made of a material including a low-resistance metal material such as titanium nitride, aluminum, titanium, copper, tungsten or the like, preferably, titanium nitride is included. The dielectric layer 93 is made of a material including a high-dielectric-constant material such as zirconium oxide, aluminum oxide, hafnium oxide or the like.

In some possible examples, as shown in FIG. 2, the semiconductor memory device further includes a second metal silicide 82. The second metal silicide 82 is disposed between the first electrode 91 and the second doped region 13. The second metal silicide 82 is in contact with both the first electrode 91 and the second doped region 13, thereby achieving electrical conduction between the first electrode 91 and the second doped region 13. By providing the second metal silicide 82, the contact resistance between the first electrode 91 and the second doped region 13 can be reduced. The second metal silicide 82 is made of a material including, for example, tungsten silicide, titanium silicide, cobalt silicide or the like. The material of the second metal silicide 82 can be the same as that of the first metal silicide 81.

The semiconductor memory device provided in the embodiments of the present disclosure includes a substrate 100, a plurality of stacked structures, a word line, a bit line 40, and a first barrier layer 50. The plurality of stacked structures are disposed on the substrate 100 and isolated from one another in a vertical direction. The stacked structure includes semiconductor layers 10. The semiconductor layer 10 includes a first doped region 11, a channel region 12, and a second doped region 13. The word line extends along the vertical direction and is adjacent to the channel region 12. The bit line 40 extends along a horizontal direction and is electrically connected to the first doped region 11. The first barrier layer 50 is disposed between adjacent bit lines 40, and the first barrier layer 50 is made of a material including a semiconductor material. The application of the semiconductor material to isolate adjacent bit lines 40 can reduce the electrical coupling between adjacent bit lines 40, thereby enhancing performance of the semiconductor memory device.

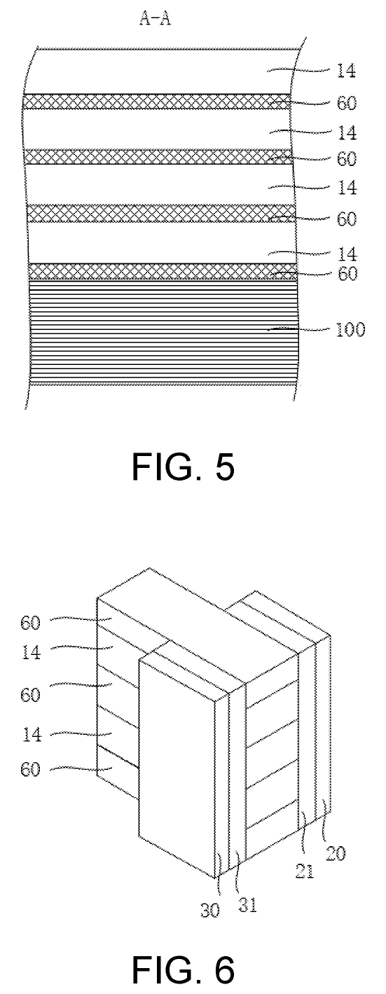

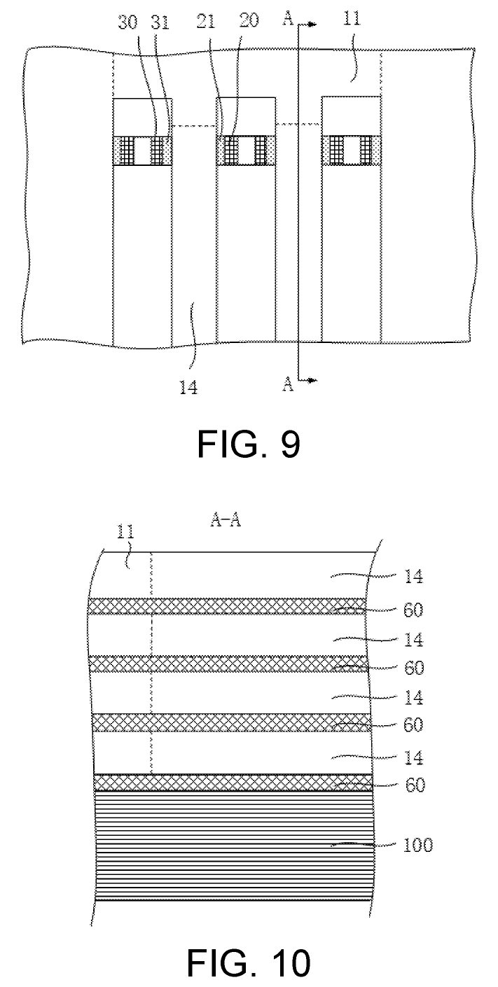

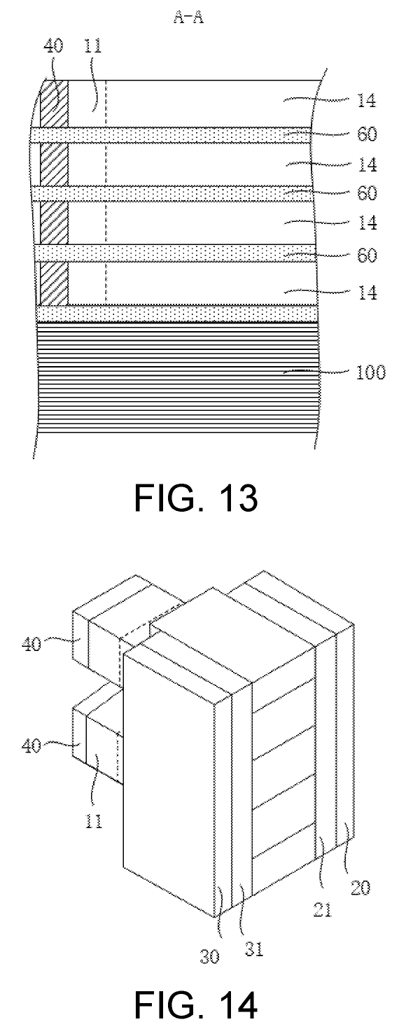

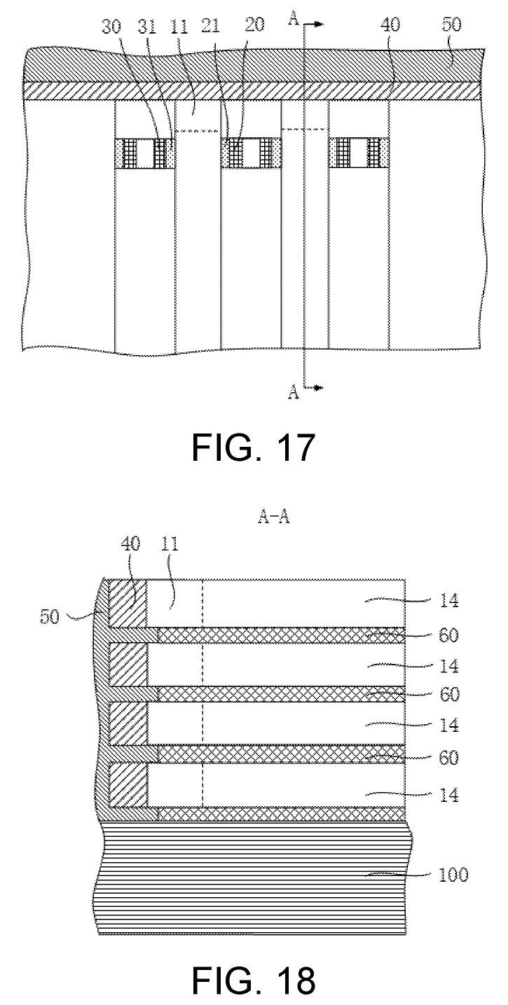

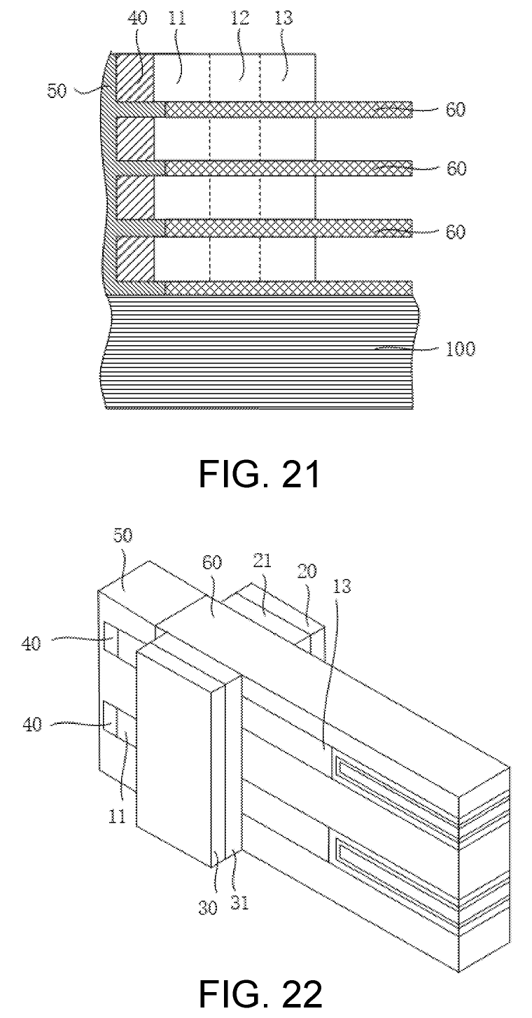

An embodiment of the present disclosure further provides a manufacturing method of a semiconductor memory device. With reference to FIGS. 1 to 24, the manufacturing method specifically includes the following steps.

Step S100: providing a substrate 100.

The substrate 100 provides support for the structures above it, such as the stacked structures, the word line, the bit lines 40, and the first barrier layer 50. The substrate 100 can be, for example, a silicon substrate 100, a silicon-containing (for example, silicon-germanium) substrate 100, a silicon-on-insulator (for example, SOI) substrate 100, or the like, which is not limited in the embodiment of the present disclosure.

Step S200: forming stacked structures, a word line, a bit line and a first barrier layer.

The stacked structures are disposed on the substrate 100 and isolated from one another along a vertical direction. The stacked structure includes semiconductor layers 10. The semiconductor layer 10 includes a first doped region 11, a channel region 12, and a second doped region 13. The word line extends along the vertical direction and is adjacent to the channel region 12. The bit line 40 extends along a horizontal direction and is electrically connected to the first doped region 11. The first barrier layer 50 is disposed between adjacent bit lines 40, and the first barrier layer 50 is made of a material including a semiconductor material.

The plurality of stacked structures are formed on the substrate 100, and are isolated from one another in the vertical direction. The plurality of stacked structures are arranged at intervals on the substrate 100, in this way, the plurality of stacked structures will not mutually conduct in the vertical direction. An arrangement direction of the plurality of stacked structures is indicated with D3 in FIG. 1. The plurality of stacked structures include semiconductor layers 10. For example, each stacked structure includes at least two semiconductor layers 10 that are arranged at intervals in the vertical direction. The semiconductor layers 10 in each stacked structure may either be in contact with the substrate 100 or be spaced apart from the substrate 100. The semiconductor layer 10 is made of a material including a semiconductor material, such as monocrystalline silicon, polycrystalline silicon, amorphous silicon, or the like.

Each semiconductor layer includes a first doped region 11, a channel region 12, and a second doped region 13 which are arranged in sequence. That is, the channel region 12 is connected to the first doped region 11 on one side and the second doped region 13 on the other side. The first doped region 11, the channel region 12, and the second doped region 13 are adjacent in sequence and are parallel to the top surface of the substrate 100. An arrangement direction of the first doped region 11, the channel region 12, and the second doped region 13 is the direction D1 shown in FIG. 1. This direction can also be considered as an extension direction of the semiconductor layers 10.

The surfaces of the first doped region 11 and the channel region 12 that face each other may be overlapping, for example, completely coincide. The surfaces of the second doped region 13 and the channel region 12 that face each other may be overlapping, for example, completely coincide. Both the first doped region 11 and the second doped region 13 can be heavily doped regions, with doping achieved, for example, through ion implantation. The first doped region 11 can serve as a drain and is connected to a bit line 40, while the second doped region 13 can serve as a source and is connected to a capacitor.

The bit line 40 is formed on the substrate 100 and extends along a horizontal direction. The horizontal direction is parallel to the top surface of the substrate 100. The bit line 40 is electrically connected to the first doped region 11. That is, the bit line 40 can be electrically conductive with the first doped region 11. A height of the bit line 40 matches a height of the semiconductor layer 10. In some possible implementations, a top surface of the bit line 40 is higher than a bottom surface of the semiconductor layers 10 to which the bit line 40 is connected and is lower than or flush with a top surface of its connected semiconductor layer 10. Alternatively, a bottom surface of the bit line 40 is higher than or flush with the bottom surface of its connected semiconductor layer 10 and is lower than the top surface of its connected semiconductor layer 10. Specifically, the top surface of the bit line 40 is flush with the top surface of its connected semiconductor layer 10, and the bottom surface of the bit line 40 is flush with the bottom surface of its connected semiconductor layer 10. That is, the bit line 40 and the semiconductor layer 10 are disposed in the same layer, facilitating fabrication of the bit line 40 and also improving transmission performance between the bit line 40 and the corresponding semiconductor layer 10.

As an example, an extension direction of the bit line 40 is parallel to an arrangement direction of the plurality of stacked structures. In this way, the bit line 40 can be connected to the plurality of semiconductor layers 10 disposed in different stacked structures, thereby simplifying the structure of the semiconductor memory device and thus facilitating an increase in storage density. The extension direction of the bit line 40 is the direction D3 shown in FIG. 1. The bit line 40 can be of a single-layer or multiple-layer structure. As an example, the bit line 40 includes a first conductor layer. The first conductor layer is made of a material including a metal material, for example, a low-resistance metal material including tungsten, aluminum, or copper. There can be a plurality of bit lines 40, and the plurality of bit lines 40 are arranged at intervals in the vertical direction to avoid connection between adjacent bit lines 40. The number of the bit lines 40 can be consistent with the number of semiconductor layers 10 in the stacked structures, enabling each semiconductor layer 10 within each stacked structure to be individually lead out through the corresponding bit line 40.

The word line is formed on the substrate 100 and extends along a vertical direction. Specifically, the word line extends along a direction away from a top surface of the substrate 100. The word line is adjacent to the channel region 12 to form a gate, thereby controlling the channel region 12 to switch on or off. The word line can be aligned with channel regions 12 of the plurality of semiconductor layers 10 in the same stacked structure, thereby simultaneously controlling the plurality of channel regions 12 to switch on or off.

In some possible implementations, the word line includes a first word line 20 and a second word line 30. The first word line 20 is adjacent to a first side of the channel region 12, and the second word line 30 is adjacent to a second side of the channel region 12. The second side and the first side of the channel region 12 face each other along an extension direction of the bit line 40. As shown in FIG. 1, the first word line 20 and the second word line 30 are respectively disposed on the first side and the second side of the channel region 12. The first word line 20 is adjacent to the first side of the channel region 12 and faces at least a portion of the channel region 12. The second word line 30 is adjacent to the second side of the channel region 12 and faces at least a portion of the channel region 12. The first side and the second side of the channel region 12 face each other along the extension direction of the bit line 40. In this way, the channel region 12 can be controlled through the two word lines.

It can be understood that in the first word line 71 and the second word line 72, regions facing the channel region 12 and aligned along the extension direction of the bit line 40 form a gate structure. The first word line 20 and the second word line 30 can either have the same or different structures. The first word line 20 and the second word line 30 can be of a single-layer or multiple-layer structure, for example, including a second conductor layer. The second conductor layer is made of a material including a semiconductor material such as doped polycrystalline silicon, doped amorphous silicon, or the like, or a low-resistance metal such as tungsten, aluminum, copper, or the like, which is not limited in the embodiments of the present disclosure.

To implement the control functions of the first word line 20 and the second word line 30, the semiconductor memory device further includes a first gate dielectric layer 21 and a second gate dielectric layer 31. The first gate dielectric layer 21 is disposed at least between the first word line 20 and the channel region 12, and the second gate dielectric layer 31 is disposed at least between the second word line 30 and the channel region 12. As an example, the first gate dielectric layer 21 extends along the vertical direction, namely, the first gate dielectric layer 21 is also disposed between the first word line 20 and the insulating layer 60. As an example, the second gate dielectric layer 31 extends along the vertical direction, namely, the second gate dielectric layer 31 is also disposed between the second word line 30 and the insulating layer 60. The first gate dielectric layer 21 and the second gate dielectric layer 31 are made of a material including silicon oxide, hafnium oxide, etc. In the extension direction of the bit line 40, thicknesses of the first gate dielectric layer 21 and the second gate dielectric layer 31 can be equal.

The first barrier layer 50 is formed between adjacent bit lines 40. For example, the first barrier layer 50 is formed (filled) at least between adjacent bit lines 40. The first barrier layer 50 is made of a material including a semiconductor material including, for example, silicon, germanium, or the like. The first barrier layer 50 is applied to isolate adjacent bit lines 40, thereby avoiding the connection between adjacent bit lines 40, and ensuring mutual isolation between adjacent bit lines 40. Meanwhile, since the first barrier layer 50 is made of a material including a semiconductor material, electrical coupling between adjacent bit lines 40 can be reduced, thereby enhancing the performance of the semiconductor memory device.

Further reference is made to FIGS. 1 and 24, in the vertical direction, an orthographic projection of the first barrier layer 50 onto the substrate 100 is spaced apart from an orthographic projection of the channel region 12 onto the substrate 100. In this way, a surface of the first barrier layer 50 facing the insulating layer 60 is located on a side of the channel region 12 away from the second doped region 13. That is, in the vertical direction, the first barrier layer 50 and the insulating layer 60 do not overlap, preventing the first barrier layer 50 from extending beneath the channel region 12, thus facilitating the formation of the first word line 20 and the second word line 30 beside the channel region 12 and ensuring the gate-control capabilities of the first word line 20 and the second word line 30.

In some possible examples, the first barrier layer 50 surrounds a portion of the bit line 40. For example, a surface of the first barrier layer 50 facing the insulating layer 60 is flush with a surface of the bit line 40 facing the semiconductor layer 10, to avoid contact and conduction between the first barrier layer 50 and the semiconductor layer 10. The first barrier layer 50 covers a portion of an upper surface of the bit line 40, a portion of a lower surface of the bit line 40, and a portion of a side surface of the bit line 40. The upper surface and the lower surface of the bit line 40 are opposite along the vertical direction. The portion of the side surface of the bit line 40 refers to a portion of a surface of the bit line 40 that is away from the semiconductor layer 10. In the extension direction of the bit line 40, a width of the first barrier layer 50 is, for example, equivalent to a width of the insulating layer 60. Specifically, in the extension direction of the bit line 40, opposing surfaces of the first barrier layer 50 are aligned with opposing surfaces of the insulating layer 60.

In some other possible examples, the first barrier layer 50 surrounds a portion of the bit line 40 and a portion of the first doped region 11. That is, the first barrier layer 50 encircles a portion of the bit line 40 and extends between adjacent first doped regions 11. The first barrier layer 50 covers a portion of an upper surface of the bit line 40, a portion of a lower surface of the bit line 40, and a portion of a side surface of the bit line 40. The upper surface and the lower surface of the bit line 40 are opposite along the vertical direction, the portion of the side surface of the bit line 40 refers to a portion of a surface of the bit line 40 that is away from the semiconductor layer 10. Furthermore, the first barrier layer 50 further covers a portion of an upper surface and a portion of a lower surface of the first doped regions 11. The upper surface and the lower surface of the first doped region 11 are opposite along the vertical direction. In the extension direction of the bit line 40, a width of the first barrier layer 50 is, for example, equivalent to a width of the insulating layer 60. Specifically, in the extension direction of the bit line 40, opposing surfaces of the first barrier layer 50 are aligned with opposing surfaces of the insulating layer 60.

According to the manufacturing method of a semiconductor memory device, a plurality of stacked structures, a word line, a bit line 40 and a first barrier layer 50 are formed on a substrate 100. The plurality of stacked structures are isolated from one another in a vertical direction. The stacked structure includes semiconductor layers 10. The semiconductor layer 10 includes a first doped region 11, a channel region 12, and a second doped region 13. The word line extends along the vertical direction and is adjacent to the channel region 12. The bit line 40 extends along a horizontal direction and is electrically connected to the first doped region 11. The first barrier layer 50 is disposed between adjacent bit lines 40, and the first barrier layer 50 is made of a material including a semiconductor material. The application of the semiconductor material to isolate adjacent bit lines 40 can reduce the electrical coupling between adjacent bit lines 40, thereby enhancing performance of the semiconductor memory device.

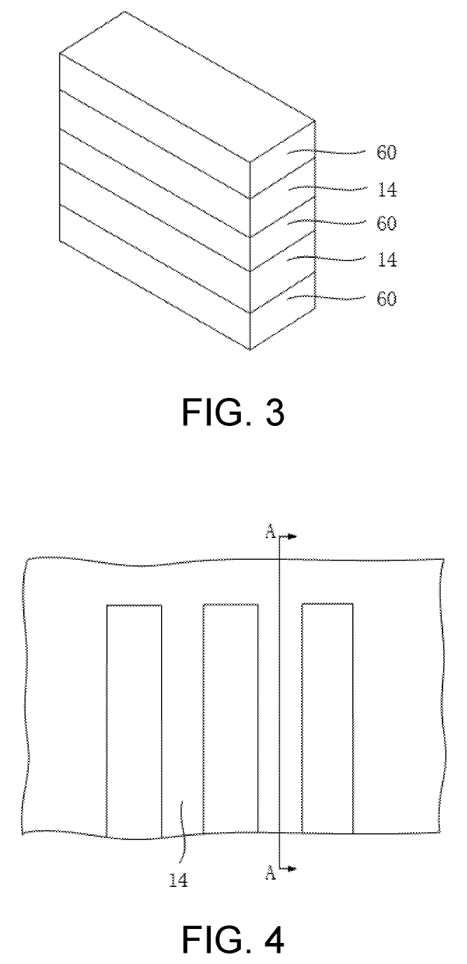

In some possible implementations, with reference to FIGS. 3 to 5, forming the stacked structures, the word line, the bit lines 40 and the first barrier layer 50 further includes: forming an insulating layer 60 disposed between adjacent semiconductor layers 10. Surfaces of the insulating layer 60 and the first barrier layer 50 that face each other are overlapping.

The insulating layer 60 is formed between adjacent semiconductor layers 10 to achieve mutual isolation between adjacent semiconductor layers 10 within the same stacked structure. As an example, the insulating layer 60 is formed (filled) at least between adjacent semiconductor layers 10 and is in complete contact with surfaces of two adjacent semiconductor layers 10 that face each other, ensuring effective isolation among the semiconductor layers 10. The insulating layer 60 is made of a material including silicon oxide, silicon nitride, phosphosilicate glass, or the like.

Surfaces of the insulating layer 60 and the first barrier layer 50 that face each other are overlapping, for example, completely coincide. In this way, the insulating layer 60 isolates adjacent semiconductor layers 10, and the first barrier layer 50 isolates adjacent bit lines 40. In addition, the bit line 40 and the semiconductor layer 10 are disposed in the same layer, and the insulating layer 60 and the first barrier layer 50 are in the same layer. This arrangement ensures reliable isolation among the overall structure formed by the bit lines 40 and the semiconductor layers 10, thereby preventing electrical conduction.

In some possible implementations, with reference to FIG. 2, forming the stacked structures, the word line, the bit lines 40 and the first barrier layer 50 further includes: forming a second barrier layer 70 disposed between the semiconductor layer 10 and the first barrier layer 50.

The second barrier layer 70 is formed between the semiconductor layer 10 and the first barrier layer 50, such that contact between the first barrier layer 50 and the semiconductor layer 10 can be avoided, thereby reducing the influence between the first barrier layer 50 and the semiconductor layer 10, and ensuring the performance of the semiconductor memory device. The second barrier layer 70 can further extend between the bit line 40 and the first barrier layer 50 to form an integrated film layer, facilitating the formation of the second barrier layer 70. The second barrier layer 70 is made of a material including an insulating material such as silicon oxide or the like.

In some possible implementations, with reference to FIGS. 22 to 24, forming the stacked structures, the word line, the bit lines 40 and the first barrier layer 50 further includes: forming first electrodes 91, a second electrode 92, and a dielectric layer 93 disposed between the first electrodes 91 and the second electrode 92. The first electrode 91 is electrically connected to the second doped region 13.

The first electrodes 91, the second electrode 92, and the dielectric layer 93 form a capacitor structure, thereby achieving a storage function of the semiconductor memory device. The first electrode 91 is electrically connected to the second doped region 13. For example, the first electrode 91 is disposed on a side of the second doped region 13 away from the first doped region 11 and is in electrical conduction with the second doped region 13. The first electrode 91, for example, covers a side surface of the second doped region 13, a portion of a top surface of the insulating layer 60, and a portion of a bottom surface of the insulating layer 60. The top surface and the bottom surface of the insulating layer 60 are oppositely disposed along the vertical direction. A plurality of first electrodes 91 can be provided, such that a corresponding first electrode 91 is disposed on a side of each second doped region 13.

In some possible examples, one second electrode 92 is provided, allowing the plurality of the first electrodes 91 to share one second electrode 92. The first electrode 91 and the second electrode 92 are made of a material including a low-resistance metal material, such as titanium nitride, aluminum, titanium, copper, tungsten or the like, preferably, titanium nitride is included. The dielectric layer 93 is made of a material including a high-dielectric-constant material such as zirconium oxide, aluminum oxide, hafnium oxide or the like.

In some possible implementations, with reference to FIG. 2, forming the stacked structures, the word line, the bit lines 40 and the first barrier layer 50 further includes: forming a first metal silicide 81 and a second metal silicide 82. The first metal silicide 81 is disposed between the bit line 41 and the first doped region 11, and the second metal silicide 82 is disposed between the first electrode 91 and the second doped region 13.

The first metal silicide 81 is disposed between the bit line 41 and the first doped region 11. The first metal silicide 81 is in contact with both the bit line 40 and the first doped region 11 and achieves electrical conduction between the bit line 40 and the first doped region 11. By providing the first metal silicide 81, the contact resistance between the bit line 40 and the first doped region 11 can be reduced. The first metal silicide 81 is made of a material including, for example, tungsten silicide, titanium silicide, cobalt silicide or the like.

The second metal silicide 82 is disposed between the first electrode 91 and the second doped region 13. The second metal silicide 82 is in contact with both the first electrode 91 and the second doped region 13, thereby achieving electrical conduction between the first electrode 91 and the second doped region 13. By providing the second metal silicide 82, the contact resistance between the first electrode 91 and the second doped region 13 can be reduced. The second metal silicide 82 is made of a material including, for example, tungsten silicide, titanium silicide, cobalt silicide or the like. The material of the second metal silicide 82 can be the same as that of the first metal silicide 81.

In the following, a detailed description of a formation process for a semiconductor memory device is provided with reference to FIGS. 1 to 14.

With reference to FIGS. 3 to 5, initial layers 14 and insulating layers 60 are sequentially stacked and alternately arranged on a substrate 100, and then etched to form isolation trenches. The isolation trenches can be formed through a patterning process.

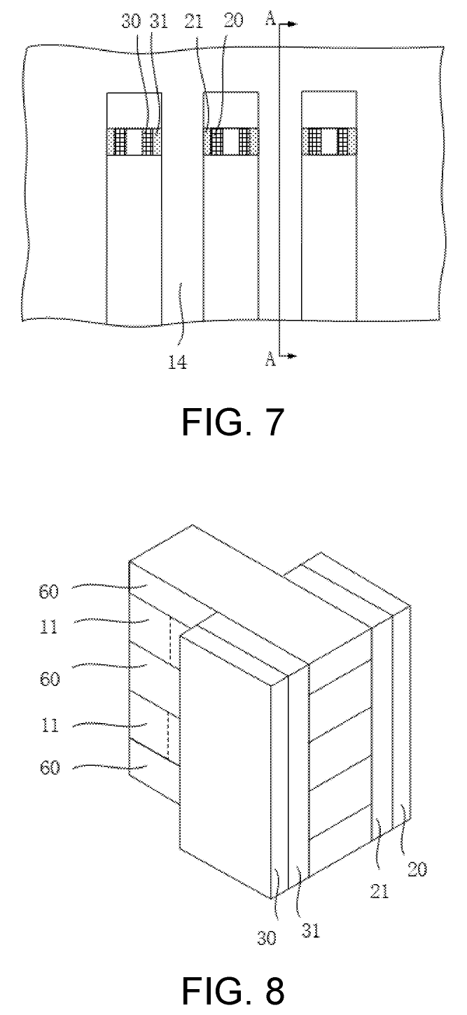

With reference to FIGS. 6 to 7, a word line is formed in the isolation trenches. The word line includes a first word line 20 disposed on a first side of the initial layer 14, and a second word line 30 disposed on a second side of the initial layer 14. The second side and the first side of the initial layer 14 face each other along a horizontal direction. Prior to the formation of the first word line 20 and the second word line 30, a first gate dielectric layer 21 and a second gate dielectric layer 31 are respectively formed on the first side and the second side of the initial layer 14. The first gate dielectric layer 21, the second gate dielectric layer 31, the first word line 20, and the second word line 30 can be formed through deposition.

With reference to FIGS. 8 to 10, first doped regions 11 are formed in the initial layers 14. The first doped region 11 is, for example, formed by ion implantation into a partial region of the initial layer 14.

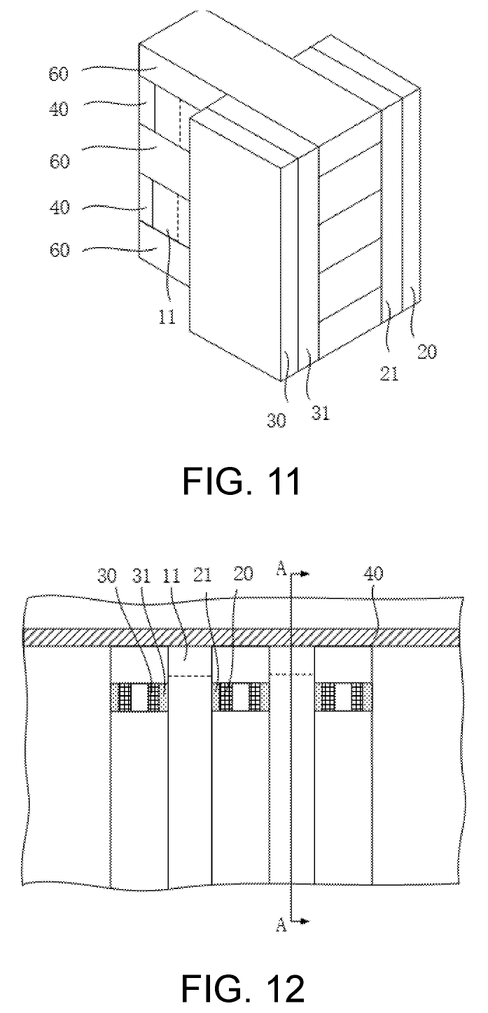

With reference to FIGS. 11 to 13, a portion of the initial layer 14 is removed to form a bit line 40 extending along a horizontal direction. The bit line 40 is connected to the first doped region 11. Specifically, the portion of the initial layer 14 is etched away, followed by deposition to form the bit line 40 that extends along the horizontal direction and is connected to the first doped region 11. Prior to the formation of the bit line 40, a first metal silicide 81 can also be formed on a corresponding end of the first doped region 11.

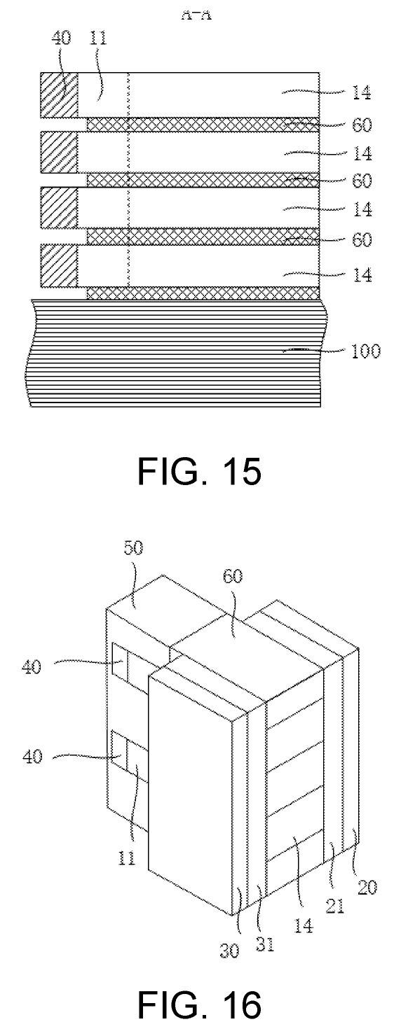

With reference to FIGS. 14 and 15, a portion of the initial layer 60 is removed to expose the bit line 40 and a portion of the first doped region 11. For example, when the portion of the initial layer 60 is etched away, an upper surface of the bit line 40, a lower surface of the bit line 40, and a side surface of the bit line 40, and a portion of an upper surface of the first doped region 11 and a portion of a lower surface of the first doped region 11, are exposed.

With reference to FIGS. 16 to 18, a first barrier layer 50 is formed. The first barrier layer 50 surrounds at least a portion of the bit line 40. The first barrier layer 50 can be formed through deposition. The first barrier layer 50 surrounds a portion of the bit line 40, and surrounds a portion of the first doped region 11. Prior to the formation of the first barrier layer 50, second barrier layers 70 are further formed through deposition. The second barrier layer 70 covers the bit line 40 and the first doped region 11 in a conformal manner. The second barrier layer 70 does not fill up a space between two bit lines 40 that are adjacent in the vertical direction.

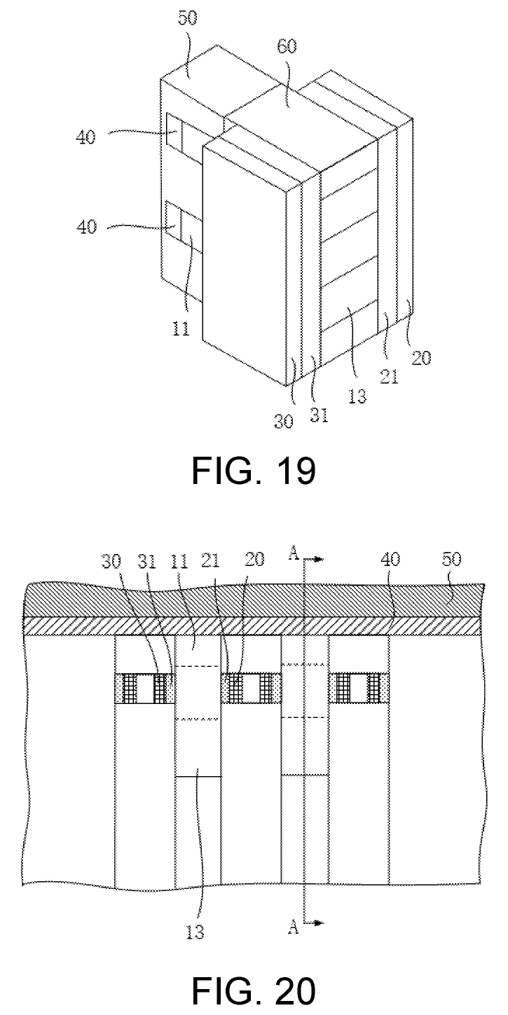

With reference to FIGS. 19 to 21, a channel region 12 and a second doped region 13 are formed to constitute a semiconductor layer 10. The second doped region 13 is, for example, formed by ion implantation. The initial layer 14 between the first doped region 11 and the second doped region 13 forms the channel region 12. Prior to or after the formation of the second doped region 13, a portion of the initial layer 14 that is away from the bit line 40 is also etched away, such that an end of the insulating layer 60 that is away from the first barrier layer 50 is exposed.

With reference to FIGS. 22 to 24, first electrodes 91, a dielectric layer 93, and a second electrode 92 are sequentially formed. As an example, on an exposed surface of the insulating layer 60, the first electrode 91 is formed through deposition on a side away from the first barrier layer 50. The first electrode 91 covers, in a conformal manner, a portion of an upper surface and a lower surface of the insulating layer 60, as well as a side surface of the second doped region 13. The first electrode 91 does not fill up the space between insulating layers 60 that are adjacent in the vertical direction. The dielectric layer 93 is then formed through deposition. The dielectric layer 93 covers, in a conformal manner, a surface of the first electrode 91 and a side surface of the insulating layer 60. The dielectric layer 93 does not fill up the remaining space between insulating layers 60 that are adjacent in the vertical direction. The second electrode 92 is then formed through deposition. The second electrode 92 covers the dielectric layer 93 and fills up the remaining space between insulating layers 60 that are adjacent in the vertical direction. Prior to the formation of the first electrode 91, a second metal silicide 82 is formed on a surface of the second doped region 13 that is away from the bit line 40.

It can be understood that during the aforementioned process, when the first word line 20 and the second word line 30 are formed, third barrier layers 110 can be further formed in the isolation trenches to form the first word line 20 and the second word line 30 through isolation, and to form the initial layers 14/semiconductor layers 10 through isolation. For example, after the formation of the channel regions 12 and the second doped regions 13, the third barrier layers 110 are deposited in the isolation trenches.

Finally, it should be noted that, those skilled in the art will readily envision other implementations of the present disclosure after considering the specification and practicing the application disclosed herein. The present disclosure is intended to cover any variations, purposes or adaptive changes of the present disclosure, and these variations, purposes or adaptive changes conform to a general principle of the present disclosure and include common knowledge or conventional technical means in the technical field not disclosed in the present disclosure. The present disclosure is not restricted to the precise structures that have been described above and illustrated in the accompanying drawings, and various modifications and alterations can be introduced without deviating from the scope thereof. The scope of the present disclosure is solely restricted by the appended claims.

What is claimed is:

1. A semiconductor memory device, comprising:
a substrate;
a plurality of stacked structures, isolated from each other, wherein the stacked structure comprises semiconductor layers, wherein the semiconductor layer comprises a first doped region, a channel region, and a second doped region;
a word line extending along a vertical direction and being adjacent to the channel region;
a bit line extending along a horizontal direction and being electrically connected to the first doped region; and
a first barrier layer disposed between adjacent bit lines, wherein the first barrier layer comprising a semiconductor material.

2. The semiconductor memory device according to claim 1, wherein the first barrier layer surrounds a portion of the bit line and a portion of the first doped region.

3. The semiconductor memory device according to claim 2, wherein the first barrier layer covers a portion of an upper surface of the bit line, a portion of a lower surface of the bit line, and a portion of a side surface of the bit line, wherein the upper surface and the lower surface of the bit line are opposite along the vertical direction.

4. The semiconductor memory device according to claim 1, wherein the stacked structure further comprises an insulating layer disposed between adjacent semiconductor layers, wherein the first barrier layer comprises a protrusion part in direct contact with the insulating layer.

5. The semiconductor memory device according to claim 1, wherein the stacked structure further comprises a second barrier layer disposed between the semiconductor layer and the first barrier layer.

6. The semiconductor memory device according to claim 1, wherein, in the vertical direction, an orthographic projection of the first barrier layer onto the substrate is spaced apart from an orthographic projection of the channel region onto the substrate.

7. The semiconductor memory device according to claim 1, further comprising a first electrode, a second electrode, and a dielectric layer disposed between the first electrode and the second electrode, wherein the first electrode is electrically connected to the second doped region.

8. The semiconductor memory device according to claim 7, further comprising a first metal silicide and a second metal silicide;
wherein the first metal silicide is disposed between the bit line and the first doped region, and the second metal silicide is disposed between the first electrode and the second doped region.

9. The semiconductor memory device according to claim 1, wherein the word line comprises a first word line and a second word line;
wherein the first word line is adjacent to a first side of the channel region, and the second word line is adjacent to a second side of the channel region, wherein the second side and the first side of the channel region are opposite along an extension direction of the bit line.

10. A manufacturing method of a semiconductor memory device, comprising:
providing a substrate; and
forming stacked structures, a word line, a bit line and a first barrier layer;
wherein the stacked structures are isolated from each other, the stacked structure comprises semiconductor layers, wherein the semiconductor layer comprises a first doped region, a channel region, and a second doped region;
the word line extends along a vertical direction and is adjacent to the channel region;
the bit line extends along a horizontal direction and is electrically connected to the first doped region;
the first barrier layer is disposed between adjacent bit lines, wherein the first barrier layer comprising a semiconductor material.

11. The manufacturing method according to claim 10, wherein the first barrier layer surrounds a portion of the bit line and a portion of the first doped region.

12. The manufacturing method according to claim 11, wherein the first barrier layer covers a portion of an upper surface of the bit line, a portion of a lower surface of the bit line, and a portion of a side surface of the bit line, wherein the upper surface and the lower surface of the bit line are opposite along the vertical direction.

13. The manufacturing method according to claim 10, wherein forming the stacked structures, the word line, the bit line and the first barrier layer further comprises:
forming an insulating layer disposed between adjacent semiconductor layers, wherein the first barrier layer comprises a protrusion part in direct contact with the insulating layer.

14. The manufacturing method according to claim 10, wherein forming the stacked structures, the word line, the bit line and the first barrier layer further comprises:
forming a second barrier layer disposed between the semiconductor layer and the first barrier layer.

15. The manufacturing method according to claim 10, wherein, in the vertical direction, an orthographic projection of the first barrier layer onto the substrate is spaced apart from an orthographic projection of the channel region onto the substrate.

16. The manufacturing method according to claim 10, wherein forming the stacked structures, the word line, the bit line and the first barrier layer further comprises:
forming a first electrode, a second electrode, and a dielectric layer disposed between the first electrode and the second electrode, wherein the first electrode is electrically connected to the second doped region.

17. The manufacturing method according to claim 16, wherein forming the stacked structures, the word line, the bit line and the first barrier layer further comprises:
forming a first metal silicide and a second metal silicide, wherein the first metal silicide is disposed between the bit line and the first doped region, and the second metal silicide is disposed between the first electrode and the second doped region.

18. The manufacturing method according to claim 10, wherein the word line comprises a first word line and a second word line;
wherein the first word line is adjacent to a first side of the channel region, and the second word line is adjacent to a second side of the channel region, wherein the second side and the first side of the channel region are opposite along an extension direction of the bit line.
